(19) United States
(12) Patent Application Publication
(10) Pub. No.: US 2024/0402250 A1
(43) Pub. Date: Dec. 5, 2024

(54) FAULT DETECTION IN PARALLEL HARDWARE

(71) Applicant: NVIDIA Corporation, Santa Clara, CA (US)

(72) Inventors: Saurabh Hukerikar, Santa Clara, CA (US); Nirmal Saxena, Los Altos Hills, CA (US); Atieh Lotfi, San Jose, CA (US); Samuel H. Duncan, Arlington, MA (US); Yanxiang Huang, San Jose, CA (US); Jason Campbell, Lake Elmo, MN (US); Paul Racunas, Landaff, NH (US)

(21) Appl. No.: 18/203,258

(22) Filed: May 30, 2023

(51) Int. Cl. G01R 31/3187; G01R 31/319

(52) U.S. Cl. CPC G01R 31/3187; G01R 31/31901

(57) ABSTRACT

In various examples, faults are detected based at least in part on result value(s) generated by hardware component(s) by performing one or more diagnostic tests in accordance with a diagnostic test pattern. The diagnostic test pattern may be used to perform an assessment of functionality of the hardware component(s) by causing the hardware component(s) to generate the result value(s), which may be used to identify one or more hardware faults (e.g., by comparing the result value(s) to expected value(s)).

### BACKGROUND

Computing hardware is susceptible to faults or component failures that may impact the ability of the hardware to accurately process data. In some circumstances, hardware faults may be permanent, such as a logic element that is fixed permanently at a particular value (e.g., 0 or 1). Hardware faults, when they persist undetected, may cause operations, applications, or other software that runs using the hardware elements to have corrupted, or otherwise incorrect data, which in safety critical contexts, such as autonomous machines, robotics, and/or data centers, may result in high-risk situations and/or conditions.

Often in safety critical applications, fault detection strategies are implemented to detect hardware faults as they occur. In some contexts, fault detection tests must be performed periodically to comply with one or more standards and/or regulations. For instance, the International Organization for Standardization (“ISO”) Standard Number 26262, titled Road vehicles-Functional safety (“ISO 26262”), specifies that 90 percent of faults in automotive components are to be detected to satisfy Automotive Safety Integrity Level B (ASIL-B). Such tests may be scheduled and then performed at a frequency that satisfies a fault-tolerant time interval (“FTTI”) or other interval that allows corrective, preventative, and/or other safety operations to be performed in the event that a critical hardware fault is detected.

Hardware fault detection presents many challenges. Some conventional approaches have used techniques such as bit parity checks or error correction codes (“ECC”). These approaches may detect faults in memory cells but may be less suitable for identifying faults in other hardware components. Generally, conventional strategies have relied on mechanisms integral to the tested hardware. For example, built-in self-tests (“BISTs”) are used to detect manufacturing defects but have been repurposed to detect faults in a system. However, these tests may be less suitable for detecting errors during runtime within a detection interval, such as an FTTI, specified by a safety regulation and/or necessary to respond to a fault. Some other techniques that may be used to identify hardware faults rely on redundant execution of operations by the hardware components. However, a truly redundant system has significant additional costs since at least twice as many hardware components are needed to provide the redundancy. Further, many of these conventional techniques are focused on fault detection in serially executing processors, such as CPUs, but these techniques are less suited for parallel processors having many specialized hardware components—such as GPUs and other accelerated hardware.

### BRIEF DESCRIPTION OF THE DRAWINGS

The present systems and methods for fault detection in parallel hardware are described in detail below with reference to the attached drawing figures, wherein:

FIG. 1 is a block diagram illustrating an example hardware fault detection system, in accordance with some embodiments of the present disclosure;

FIG. 2 is a block diagram showing a method of hardware fault detection, in accordance with some embodiments of the present disclosure;

FIG. 3 is an example processor, in accordance with some embodiments of the present disclosure;

FIG. 4 is a diagram showing an example test pattern assignment, in accordance with some embodiments of the present disclosure;

FIG. 5 is a diagram showing an example operation test pattern assignment, in accordance with some embodiments of the present disclosure;

FIG. 6 is a flow diagram showing a method for performing hardware fault detection, in accordance with some embodiments of the present disclosure;

FIG. 7A is an illustration of an example autonomous vehicle, in accordance with some embodiments of the present disclosure;

FIG. 7B is an example of camera locations and fields of view for the example autonomous vehicle of FIG. 7A, in accordance with some embodiments of the present disclosure;

FIG. 7C is a block diagram of an example system architecture for the example autonomous vehicle of FIG. 7A, in accordance with some embodiments of the present disclosure;

FIG. 7D is a system diagram for communication between cloud-based server(s) and the example autonomous vehicle of FIG. 7A, in accordance with some embodiments of the present disclosure; and

FIG. 8 is a block diagram of an example computing device suitable for use in implementing some embodiments of the present disclosure.

### DETAILED DESCRIPTION

In the following description, numerous specific details are set forth to provide a more thorough understanding of at least one embodiment. However, it will be apparent to one skilled in the art that the inventive concepts may be practiced without one or more of these specific details.

Systems and methods are disclosed related to fault detection in parallel hardware. For example, such systems and/or methods may use fault detection diagnostic techniques that use a library of software-based tests to thoroughly and/or efficiently test hardware components, such as components used by a GPU, to detect and/or identify one or more permanent hardware faults within one or more hardware components. The disclosed diagnostic techniques may perform one or more diagnostic tests that test various hardware components, such as memory, compute units, tensor cores, processors, and/or logic units. Each hardware component, and the connections and/or data paths associated with them, may be tested according to a testing frequency. This testing frequency may be selected and/or configured such that each hardware component is tested at least once per cycle according to the testing frequency, such as an FTTI. The diagnostic tests may be scheduled among other operations. For example, the diagnostic tests may be scheduled such that they are performed with other operations, such as operations associated with autonomous or semi-autonomous machines and/or other actively running systems. In one example, an autonomous or semi-autonomous machine may devote 10% of its operational time and/or resources to performing one or more diagnostic tests of hardware components while the remaining 90% may be reserved for performing ongoing processes unrelated to the diagnostic tests.

The diagnostics tests include multiple tests performed across various components. For example, a diagnostic test may include, but is not limited to, one or more of the following:
1. A test for vector operations for integer point and/or floating-point addition, multiplication, dot product and accumulate, min/max, compare and set, predicate, logical operations, shift operations, integer to floating point conversion, and packing, for various integer and floating type representations including but not limited to: UINT32, INT32, INT8, UINT8, INT4, FP64, FP16, FP8, BF16, and/or TF32;
2. A test of matrix multiplication operations to diagnose tensor core data paths;
3. A test of bit operations;
4. A test of atomic operations on shared memory and global memory for integer and/or floating-point operations;
5 A test of uniform data path integer and/or floating-point arithmetic and logical operations;
6. A test of L1 and L2 data/instruction caches;
7. A test for a memory management unit, including the translation lookaside buffer (“TLB”), for various addressing modes;
8. A test for various intermediate first in, first out (“FIFO”) memory, data structures, and/or buffers;
9. A test of load and/or store(s) from global memory with different operand sizes;
10. A test of load and/or store(s) from local memory;
11. A test of asynchronous global to shared memory loads;
12. A test for constant cache diagnostics through stride accesses for read operations;
13. A test for misaligned L1/L2 cache accesses and/or missed buffers;
14. A test of operations following cache compression; and/or
15. A test of data transfer between hardware and host devices.

In some embodiments, hardware diagnostic tests may be performed using an application programming interface (“API”) and/or instructions that is/are to schedule various tests among hardware components. Upon invocation of the API, test patterns specific to particular hardware may be accessed from one or more libraries and/or other storage devices. In some examples, the test patterns may be defined algorithmically such that test patterns may be generated to cover each possible operation, sub-component, and/or data value for a particular hardware component. The test patterns may be algorithmically generated to provide universal coverage and/or pseudo-random patterns of inputs to the hardware components such that the test patterns provide complete coverage of the hardware components and functionality. For example, a test pattern designed for one or more processors may include one or more compute functions launched on the processors (e.g., to perform matrix operations), where the compute functions are to target each compute thread of the processors in addition to each associated data path, register, shared memory address, and local memory address. In such an example, functions may be invoked to cause blocks of threads to execute concurrently on each processor by occupying each execution path within the processors.

In some examples, the test pattern is based on the characteristics of a specific component (e.g., tensor core, cache, adder, etc.) being tested. For example, a test pattern may be generated to test each memory cell in a memory component of a processor, such as an L1 cache and/or an L2 cache.

Performing the diagnostic tests using a test pattern may include providing one or more input values to one or more hardware components, obtaining one or more output values, and comparing the output value(s) to one or more expected values associated with the test pattern. For example, a test of a read/write operation to memory may attempt to write an input value to a particular memory address, subsequently read a value stored at that address as an output value, and compare the output value to an expected value (e.g., the input value) associated with the test pattern (e.g., the read/write operation) to obtain a comparison result value. As another example, a matrix multiplication operation may be tested by providing one or more input matrices to one or more tensor cores that may output one or more result matrices, and comparing the one or more output matrices to one or more expected matrices associated with the test pattern (e.g., the matrix multiplication operation) to obtain a comparison result value. In some examples, before the comparison is performed, a hash function may be applied to output or result values generated in response to a test pattern, to generate a result hash value. The result hash value may be compared to an expected hash value associated with the test pattern to determine whether the tested component is exhibiting the correct operation. For example, if a result hash value is equal to an expected hash value, the corresponding component may be identified as operating correctly. On the other hand, if the result hash value does not match the expected hash value, the corresponding component may be identified as operating incorrectly and/or as exhibiting a potential fault. In some examples, if a fault is detected (e.g., by failure of one or more diagnostic tests), an indication may be provided indicating the potential fault and/or other information associated with the corresponding hardware component.

In some embodiments, one or more actions may be performed in response to identifying one or more hardware faults. For example, an autonomous machine may use one or more control components to perform mitigating operations, such as fail-safe and/or other safety operations, in response to one or more hardware faults being detected and/or identified. As another example, a data center may perform one or more failover operations in response to identifying one or more hardware components exhibiting potential faults.

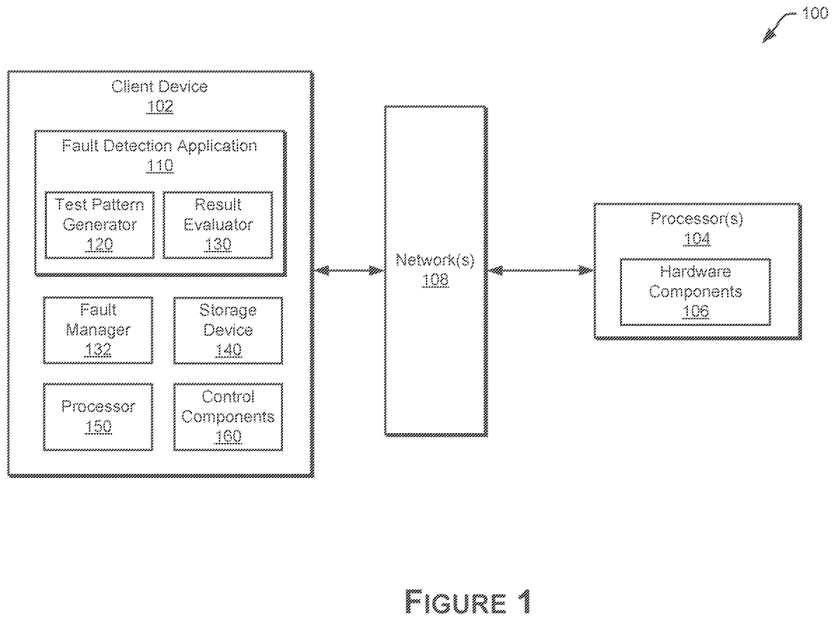

With reference to FIG. 1, FIG. 1 is a block diagram illustrating an example hardware fault detection system 100 (“system 100”), in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

System 100 may include a client device 102, one or more network(s) 108, and/or one or more processor(s) 104. Processor(s) 104 may include and/or be connected to one or more hardware components 106. Client device 102 may include a fault detection application 110, a fault manager 132, a storage device 140, one or more processors 150, and/or one or more control components 160.

Components of system 100 may be configured to communicate across one or more networks, such as network(s) 108, and/or other network types described herein. Network(s) 108 may include one or more networks of any number of network types. In some examples, network(s) 108 include one or more data bus protocols and/or topologies (e.g., a Controller Area Network (“CAN”), FlexRay, Ethernet, etc.). One or more components of system 100 may be configured to use one or more network interfaces to connect the one or more components of system 100 over network(s) 108. Client device 102 may include one or more components for performing one or more operations (e.g., fault detection, safety validations, etc.) associated with an autonomous or semi-autonomous machine. For example, client device 102 may include one or more components for performing one or more diagnostic tests of hardware components 106, one or more components for performing calculations (e.g., using processor(s) 104), and/or one or more components for making predictions corresponding to an autonomous machine. As an example, client device 102 may generate and perform one or more diagnostic tests, such as tests to be used to validate, or otherwise access the performance and/or functionality of one or more hardware components of an autonomous machine, a semi-autonomous machine, and/or other hardware device.

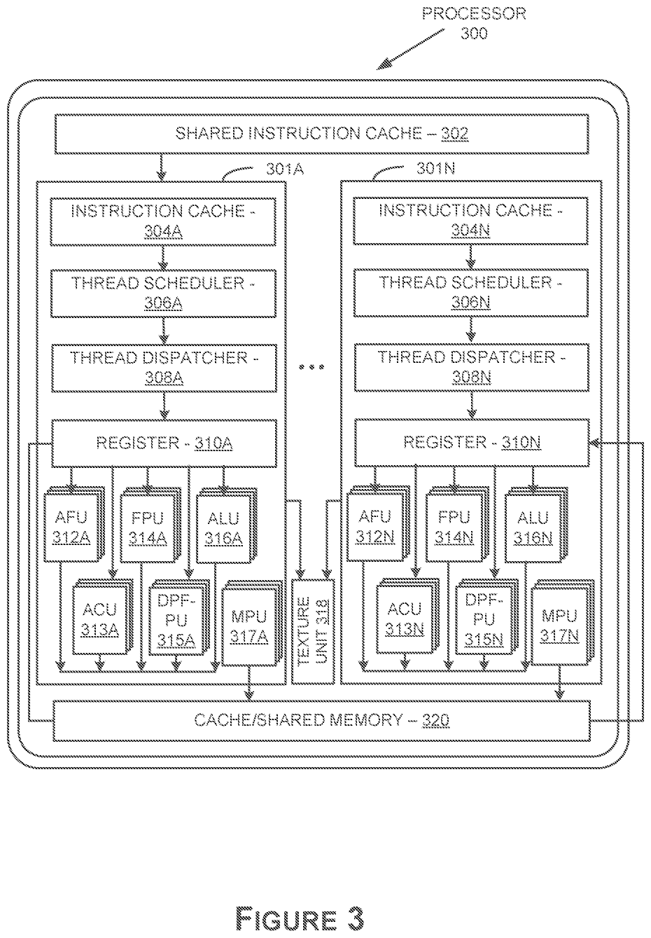

Processor(s) 104 may include one or more components for processing data associated with one or more autonomous or semi-autonomous machine operations. In some embodiments, processor(s) 104 may provide additional and/or alternative processing to the processing performed by client device 102. In some examples, processor(s) 104 may perform processing associated with system 100. For example, processor(s) 104 may be configured to process measurement data from one or more inertial measurement unit sensors, and/or other sensors, such as LiDAR and cameras associated with client device 102. In some embodiments, processor(s) 104 may be evaluated by fault detection application 110 to detect one or more hardware faults associated with one or more hardware components 106 of processor(s) 104. Hardware components may include one or more instruction caches, one or more texture units, cache/shared memory, one or more thread schedulers, one or more thread dispatchers, one or more registers, and/or one or more compute function units, such as those described below in relation to FIG. 3.

Fault detection application 110 may include one or more components configured to detect one or more hardware faults associated with processor(s) 104. For example, fault detection application 110 may be used to detect one or more faults within one or more hardware components 106 (e.g., tensor core, cache, adder, ALU, etc.) of processor(s) 104 and/or connected thereto. Fault detection application 110 may include a test pattern generator 120 and/or a result evaluator 130.

Test pattern generator 120 may include one or more components configured to generate and/or access one or more diagnostic test patterns, such as those described above, used to detect one or more hardware faults in association with processor(s) 104. Test patterns may be generated by test pattern generator 120 such that a portion of hardware components 106 is evaluated for potential faults. For example, test pattern generator 120 may generate one or more test patterns that assess one or more operations of hardware components 106. In at least one embodiment, test patterns generated by test pattern generator 120 may be stored (e.g., in storage device 140), such that the test patterns may be reused for subsequent fault detection operations.

In some examples, one or more test patterns generated by test pattern generator 120 and/or accessed from storage (e.g., storage device 140) may be provided to processor(s) 104 to be performed. For example, processor(s) 104 may perform one or more operations in accordance with one or more test patterns. In such an example, processor(s) 104 may perform operations using instructions and/or values indicated by the one or more test patterns. Processor(s) 104 may perform one or more diagnostic tests using hardware components 106. In at least one embodiment, processor(s) 104 may be caused to execute one or more instructions corresponding to one or more test patterns in parallel. In some examples, processor(s) 104 may generate one or more output values and/or indications in response to performing one or more test patterns, such as the test patterns generated by test pattern generator 120.

In at least one embodiment, result evaluator 130 includes one or more components configured to evaluate one or more result values. For example, result evaluator 130 may receive one or more output values calculated by processor(s) 104 and may use the one or more output values to determine one or more result values, which may be used to determine whether a potential fault may be identified. In some examples, result evaluator 130 may compare one or more result values to one or more expected result values. In such an example, result values generated by processor(s) 104 in response to a test pattern may be compared to expected result values associated with that test pattern by result evaluator 130. In at least one embodiment, result evaluator 130 may access one or more expected result values from storage device 140 and/or may calculate the expected result values using one or more processors, such as processor(s) 150.

In some embodiments, result evaluator 130 may generate (e.g., as the one or more result values) a fault status based on comparing one or more output values generated by processor(s) 104 to one or more expected values. For example, result evaluator 130 may generate a fault status that indicates that one or more faults were detected in processor(s) 104 (or that no faults were detected). In some examples, result evaluator 130 may apply a hash function to the output or result values generated by processor(s) 104 in response to a test pattern, to generate a result hash value. In such an example, result hash value may be compared by result evaluator 130 to an expected hash value associated with the test pattern to determine whether one or more of hardware components 106 are exhibiting correct operation (e.g., fault-free operation). In some examples, if a fault is detected (e.g., by failure of one or more diagnostic tests), an indication may be provided to fault manager 132 as a fault status that indicates and/or identifies one or more potential faults and/or provides other information associated with one or more hardware components 106 corresponding to the one or more potential faults. In some examples, result evaluator 130 may provide a fault status to fault manager 132.

Fault manager 132 includes one or more components configured to perform one or more actions based on the fault status generated by result evaluator 130. For example, based on a fault status, fault manager 132 may indicate one or more actions (e.g., one or more corrective operations) to be performed (e.g., using control components 160). Fault manager 132 may make one or more decisions based on the fault status. For example, fault manager 132 may determine one or more operations to perform based on fault status indicating a threshold number of faults detected in relation to processor(s) 104. In some examples, fault manager 132 may cause one or more operations to be performed by control components 160. For example, fault manager 132 may cause control components 160 to perform one or more mitigating operations, such as one or more fail-safe operations and/or one or more other safety operations, in response to the fault status received by fault manager 132 identifying one or more hardware faults. The mitigating operation(s) may be performed with respect to one or more of the hardware components 106 associated with (e.g., identified by) the fault status.

The client device 102 may include memory (not shown) that may be implemented as one or more non-transitory processor-readable medium storing processor executable instructions that when executed by the processor(s) 150 implement fault detection application 110, fault manager 132, control components 160, and/or the like. The memory (not shown) may be implemented as or using storage device 140. The processor(s) 150 may include one or more circuits that perform at least a portion of the instructions. The processor(s) 150 may be implemented, for example, using a main central processing unit (“CPU”) complex, one or more microprocessors, one or more microcontrollers, one or more graphics processing units (“GPU(s)”), one or more data processing units (“DPU(s)”), and/or the like. By way of additional non-limiting examples, the memory (e.g., one or more non-transitory processor-readable medium) may be implemented, for example, using volatile memory (e.g., dynamic random-access memory (“DRAM”)) and/or nonvolatile memory (e.g., a hard drive, a solid-state device (“SSD”), and/or the like). The client device 102 may include a user interface (not shown) that a user may use to enter user input into the client device 102. The user interface (not shown) may include a display device (not shown) that the user may use to view information generated and/or displayed by the client device 102. The processor(s) 150, the user interface, and/or the memory may communicate with one other over one or more connections, such as a bus, a Peripheral Component Interconnect Express (“PCIe”) connection (or bus), and/or the like.

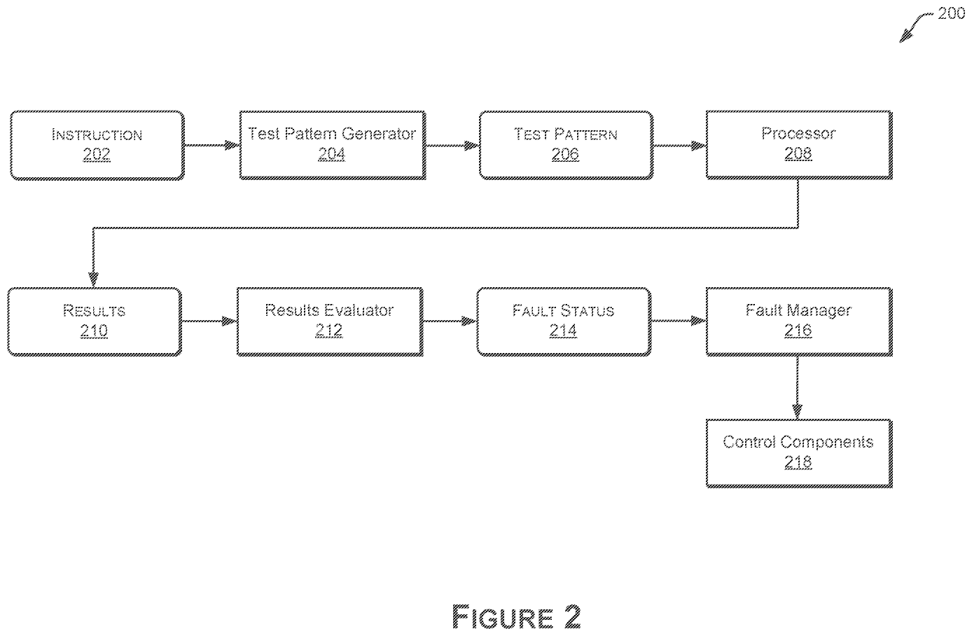

FIG. 2 is a block diagram showing a method 200 of hardware fault detection, in accordance with some embodiments of the present disclosure. By way of a non-limiting example, the method 200 may be performed by the processor(s) 150 (see FIG. 1). Referring to FIG. 2, a process (e.g., fault detection application 110 illustrated in FIG. 1) sends instruction 202 to test pattern generator 204. Test pattern generator 204 may be implemented as or using test pattern generator 120 (see FIG. 1). In some embodiments, test pattern generator 204 receives instruction 202, which instructs test pattern generator 204 to generate and/or access a test pattern 206. For example, instruction 202 may cause test pattern generator 204 to access test pattern 206 from one or more storage devices, such as storage device 140 of FIG. 1. In other examples, test pattern generator 204 may generate test pattern based at least in part on instruction 202. Test pattern generator 204 may determine test pattern 206 in accordance with one or more characteristics and/or components of processor 208 to be tested. Test pattern 206 may be provided to, or otherwise accessed by, processor 208. Processor 208 may be implemented as or using one or more of processor(s) 104 (see FIG. 1).

In at least one embodiment, processor 208 may perform test pattern 206. For example, processor 208 may perform one or more operations and/or computations according to test pattern 206. Processor 208 may generate and/or calculate one or more results 210 as a result of performing test pattern 206. In some examples, results 210 may include one or more values used by results evaluator 212 to detect one or more faults in processor 208. As an example, a test pattern 206 that tests an arithmetic logic unit (“ALU”) of processor 208 may cause processor 208 to perform one or more integer addition and/or subtraction operations to generate one or more output values as results 210. Once results 210 have been generated by processor 208, they may be provided to and/or accessed by results evaluator 212. Results evaluator 212 may be implemented as or using results evaluator 130 (see FIG. 1).

Results evaluator 212 may receive results 210 that may have been generated by processor 208 and may determine whether the results 210 indicate one or more hardware faults associated with processor 208. In some examples, results evaluator 212 may compare results 210 to one or more expected result values associated with test pattern 206. In such an example, if results 210 match the expected values, results evaluator 212 may determine that performing the test pattern 206 did not cause any faults in processor 208. In other examples, if results 210 do not match expected values, results evaluator 212 may determine that performing the test pattern 206 did cause one or more faults in processor 208. In some embodiments, results evaluator 212 may generate a fault status 214 based on finding one or more faults and/or an absence of any faults in relation to processor 208. In at least one embodiment, fault status 214 may include one or more indications of one or more faults associated with processor 208 and/or test pattern 206. In some embodiments, fault status 214 may be provided to fault manager 216. Fault manager 216 may be implemented as or using fault manager 132 (see FIG. 1).

Fault manager 216 may access fault status 214 and make one or more decisions based on the fault status 214. For example, fault manager 216 may determine one or more operations to perform based on fault status 214 indicating at least a threshold number of faults were detected in relation to processor 208. In some examples, based on the fault status 214, fault manager 216 may cause one or more operations to be performed by control components 218. For example, control components 218 may perform mitigating operations, such as fail-safe and/or other safety operations, in response to one or more hardware faults being detected and/or identified by fault manager 216. Control components 218 may be implemented as or using control components 160 (see FIG. 1).

FIG. 3 illustrates an example processor 300, in accordance with at least one embodiment. In at least one embodiment, processor 300 may be included within processor(s) 104 of FIG. 1. In at least one embodiment, processor 300 may be a graphics processing unit (“GPU”). In at least one embodiment, processor 300 includes one or more hardware components which may be configured to perform one or more types of operations. In at least one embodiment, processor 300 includes one or more hardware components which may assessed using one or more diagnostic test patterns, such as those described above. Hardware components of processor 300 may include a shared instruction cache 302, a texture unit 318, and a cache/shared memory 320 that are common to execution resources within processor 300. In at least one embodiment, processor 300 includes one or more cores and may include multiple slices 301A-301N or partition for each core. A graphics processor (e.g., processor(s) 104 illustrated in FIG. 1) may include multiple instances of processor 300. Slices 301A-301N may include support logic including local instruction caches 304A-304N, respectively, thread schedulers 306A-306N, respectively, thread dispatchers 308A-308N, respectively, and sets 310A-310N, respectively, of registers. The sets 310A-310N may each include any number of registers, including a single register, and the sets 310A-310N may include the same number of registers or at least two of the sets 310A-310N may include different numbers of registers. In at least one embodiment, slices 301A-301N may include sets 312A-312N, respectively, of additional function units (“AFUs”), sets 314A-314N, respectively,, of floating-point units (“FPUs”), sets 316A-316N, respectively, of integer arithmetic logic units (“ALUs”), sets 313A-313N, respectively, of address computational units (“ACUs”), sets 315A-315N, respectively, of double-precision floating-point units (“DPFPUs”), and sets 317A-317N, respectively, of matrix processing units (“MPUs”). The sets 312A-312N may each include any number of AFUs, including a single AFU, and the sets 312A-312N may include the same number of AFUs or at least two of the sets 312A-312N may include different numbers of AFUs. The sets 313A-313N may each include any number of ACUs, including a single ACU, and the sets 313A-313N may include the same number of ACUs or at least two of the sets 313A-313N may include different numbers of ACUs. The sets 314A-314N may each include any number of FPUs, including a single FPU, and the sets 314A-314N may include the same number of FPUs or at least two of the sets 314A-314N may include different numbers of FPUs. The sets 315A-315N may each include any number of DPFPUs, including a single DPFPU, and the sets 315A-315N may include the same number of DPFPUs or at least two of the sets 315A-315N may include different numbers of DPFPUs. The sets 316A-316N may each include any number of ALUs, including a single ALU, and the sets 316A-316N may include the same number of ALUs or at least two of the sets 316A-316N may include different numbers of ALUs. The sets 317A-317N may each include any number of MPUs, including a single MPU, and the sets 317A-317N may include the same number of MPUs or at least two of the sets 317A-317N may include different numbers of MPUs. In at least one embodiment, the processor 300 is referred to as a compute unit or computing unit.

In at least one embodiment, sets 314A-314N of FPUs may perform single-precision (e.g., 32-bit) and half-precision (e.g., 16-bit) floating point operations, while sets 315A-315N of DPFPUs perform double precision (e.g., 64-bit) floating point operations. In at least one embodiment, the sets 316A-316N of ALUs may perform variable precision integer operations at 8-bit, 16-bit, and/or 32-bit precision, and may be configured for mixed precision operations. In at least one embodiment, the sets 317A-317N of MPUs may also be configured for mixed precision matrix operations, including half-precision floating point and/or 8-bit integer operations. In at least one embodiment, the sets 317A-317N of MPUs may perform a variety of matrix operations to accelerate Compute Unified Device Architecture (“CUDA”) programs, including enabling support for accelerated general matrix to matrix multiplication (“GEMM”). In at least one embodiment, the sets 312A-312N of AFUs may perform additional logic operations not supported by floating-point or integer units, including trigonometric operations (e.g., Sine, Cosine, etc.).

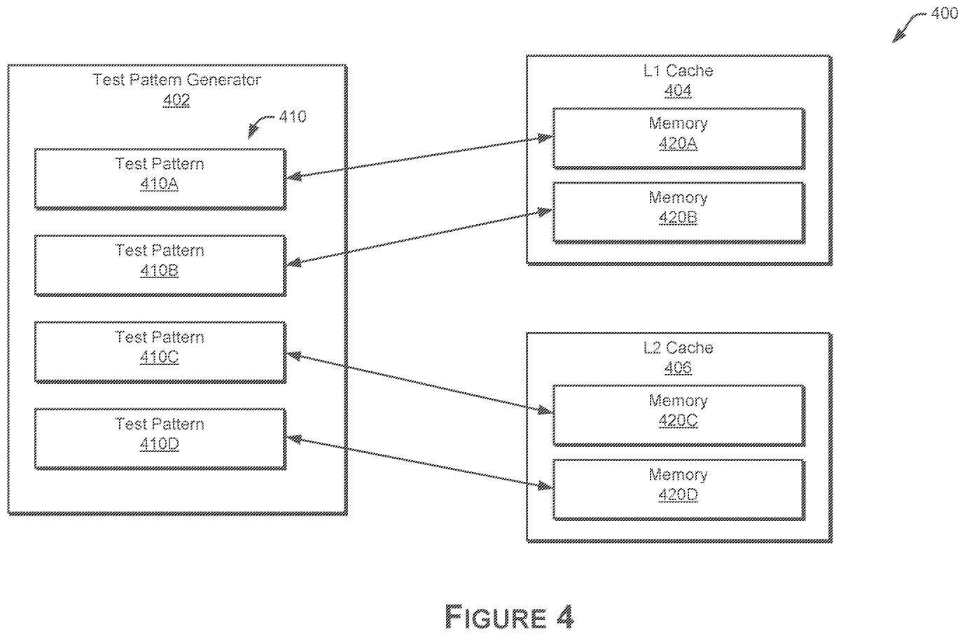

FIG. 4 is an example test pattern assignment 400, in accordance with some embodiments of the present disclosure. Test pattern assignment 400 may be implemented at least in part by test pattern generator 402 and one or more hardware components (e.g., hardware components 106 illustrated in FIG. 1), such as L1 cache 404 and/or L2 cache 406. For example, the test pattern generator 402 may obtain one or more test patterns that are to be performed by a processor (e.g., the processor(s) 104 illustrated in FIG. 1, the processor 208 illustrated in FIG. 2, and/or the like) to detect whether the test patterns cause any faults to occur in the hardware component(s). Test pattern generator 402 may be implemented as or using test pattern generator 120 (see FIG. 1) and/or test pattern generator 204 (see FIG. 2).

Test pattern assignment 400 may include one or more test patterns such as test pattern 410A, test pattern 410B, test pattern 410C, and/or test pattern 410D (referred to singularly or collectively herein as test patterns 410). In some examples, L1 cache 404 may include one or more portions of memory, such as memory 420A and/or memory 420B, each of which may include one or more hardware components corresponding to one or more memory addresses. Similarly, in some examples, L2 cache 406 may include one or more portions of memory, such as memory 420C and/or memory 420D, each of which may include one or more hardware components corresponding to one or more memory addresses.

In at least one embodiment, each of test patterns 410 may be generated by test pattern generator 402 to test one or more particular hardware components for potential faults. For example, test pattern 410A may be configured to test memory 420A of L1 cache 404, while test pattern 410B may be configured to test memory 420B of L1 cache 404. As another example, test pattern 410C may be configured to test memory 420C of L2 cache 406, while test pattern 410D may be configured to test memory 420D of L2 cache 406. In some examples, a plurality of test patterns (such as test patterns 410) may be used to test a single component, while in at least one other example, a single test pattern may be used to test a plurality of components.

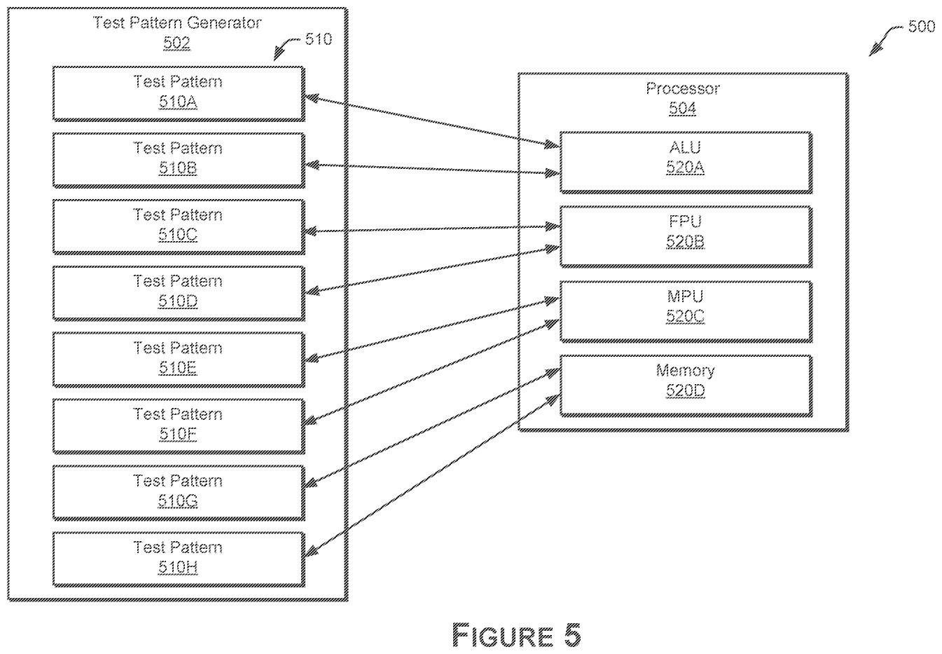

FIG. 5 is an example operation test pattern assignment 500, in accordance with some embodiments of the present disclosure. Operation test pattern assignment 500 may be implemented at least in part by test pattern generator 502 and one or more hardware components (e.g., hardware components 106 illustrated in FIG. 1) of a processor 504. For example, the test pattern generator 502 may obtain one or more test patterns that are to be performed by processor 504 to detect whether the test patterns cause any faults to occur in the hardware component(s). Test pattern generator 502 may be implemented as or using test pattern generator 120 (see FIG. 1) and/or test pattern generator 204 (see FIG. 2). Processor 504 may be implemented as or using the processor(s) 104 (see FIG. 1) and/or the processor 208 (see FIG. 2).

Operation test pattern assignment 500 may include one or more test patterns such as test pattern 510A, test pattern 510B, test pattern 510C, test pattern 510D, test pattern 510E, test pattern 510F, test pattern 510G, and/or test pattern 510H (referred to singularly or collectively herein as test patterns 510). Operation test pattern assignment 500 may include one or more hardware components, such as ALU 520A, FPU 520B, MPU 520C, and/or memory 520D. In some examples, ALU 520A, FPU 520B, MPU 520C, and/or memory 520D may be included in processor 504 and/or one or more other processors, such as those described above. By way of a non-limiting example, the ALU 520A may be a member of the set 316A (see FIG. 3) of ALUs, FPU 520B may be a member of the set 314A (see FIG. 3) of FPUs, and/or MPU 520C may be a member of the set 317A (see FIG. 3) of MPUs.

In at least one embodiment, each of test patterns 510 may be generated by test pattern generator 502 and used to detect potential faults by testing one or more particular operations associated with one or more hardware components. For example, test pattern 510A may be configured to test integer addition operations performed by ALU 520A, while test pattern 510B may be configured to test integer subtraction operations performed by ALU 520A. As another example, test pattern 510C may be configured to test floating-point addition operations performed by FPU 520B, while test pattern 510D may be configured to test floating-point subtraction operations performed by FPU 520B. As another example, test pattern 510E may be configured to test matrix multiplication operations performed by MPU 520C, while test pattern 510F may be configured to test matrix transform operations performed by MPU 520C. As another example, test pattern 510G may be configured to test memory read operations performed by memory 520D, while test pattern 510H may be configured to test memory write operations performed by memory 520D. In some examples, a plurality of test patterns (such as test patterns 510) may be configured to test a single operation, while in at least one other example, a single test pattern may be configured to test a plurality of distinct operations for one or more components.

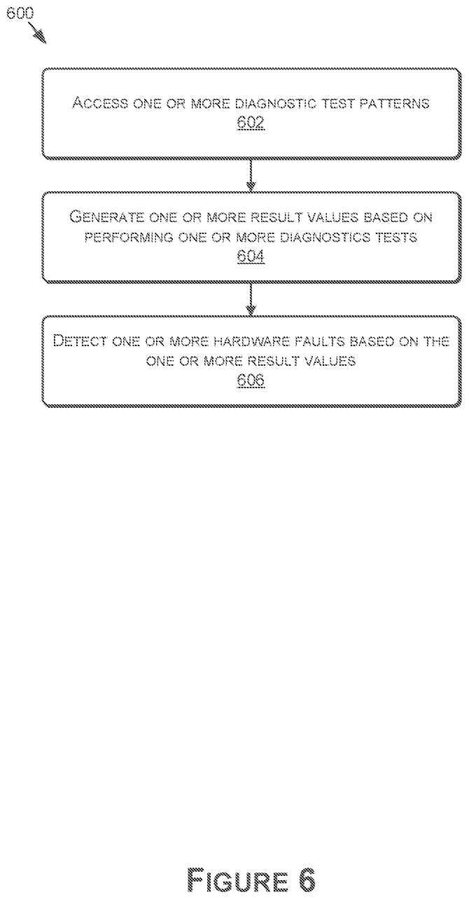

Now referring to FIG. 6, each block of a method 600, described herein, comprises a computing process that may be performed using any combination of hardware, firmware, and/or software. For instance, various functions may be carried out by a processor executing instructions stored in memory. Method 600 may also be embodied as computer-usable instructions stored on computer storage media. Method 600 may be provided by a standalone application, a service or hosted service (standalone or in combination with another hosted service), or a plug-in to another product, to name a few. In addition, method 600 is described, by way of example, with respect to system 100 of FIG. 1. However, these methods may additionally or alternatively be executed by any one system, or any combination of systems, including, but not limited to, those described herein.

FIG. 6 is a flow diagram showing method 600 for performing hardware fault detection, in accordance with some embodiments of the present disclosure. At block 602, fault detection application 110 (see FIG. 1) (e.g., performed by processor(s) 150 illustrated in FIG. 1) accesses one or more diagnostic test patterns. For example, one or more diagnostic test patterns generated by test pattern generator 120 (see FIG. 1) may be accessed and/or provided to one or more processors, such as processor(s) 104 (see FIG. 1), by fault detection application 110. In at least one embodiment, fault detection application 110 provides one or more input values associated with the one or more diagnostic test patterns to processor(s) 104.

At block 604, processor(s) 104 (see FIG. 1) performs and/or causes one or more of hardware components 106 (see FIG. 1) to perform the diagnostic test patterns to generate one or more result values. For example, one or more result values may be generated by processor(s) 104 based on one or more diagnostic test patterns accessed by fault detection application 110 and provided to processor(s) 104 by fault detection application 110 at block 602. In such an example, processor(s) 104 may perform and/or cause one or more of hardware components 106 (see FIG. 1) to perform one or more operations associated with the diagnostic test patterns.

At block 606, fault detection application 110 (see FIG. 1) performs and/or causes result evaluator 130 (see FIG. 1) to detect one or more hardware faults based on the one or more result values. For example, based on result values generated by processor(s) 104 and/or hardware components 106 in response to performing a diagnostic test pattern at block 604, result evaluator 130 may determine that one or more hardware faults are detected in association to processor(s) 104. After block 606, method 600 may terminate.

The systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. The systems and methods described herein may be used in augmented reality, virtual reality, mixed reality, robotics, security and surveillance, autonomous or semi-autonomous machine applications, and/or any other technology spaces in which two or more clocks are synchronized.

The systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets, cloud computing, web-hosted services or web-hosted platforms, and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models—such as large language models (LLMs) that process textual, image, sensor, audio, and/or other data types, systems for performing light transport simulation, systems for performing collaborative content creation for 3D assets, systems implemented at least partially using cloud computing resources, systems for implementing web-hosted services (e.g., for program optimization at runtime) or web-hosted platforms (e.g., integrated development environments that include program optimization as a service), as an application programming interface (“API”) between two or more separate applications or systems, and/or other types of systems.

### EXAMPLE AUTONOMOUS VEHICLE

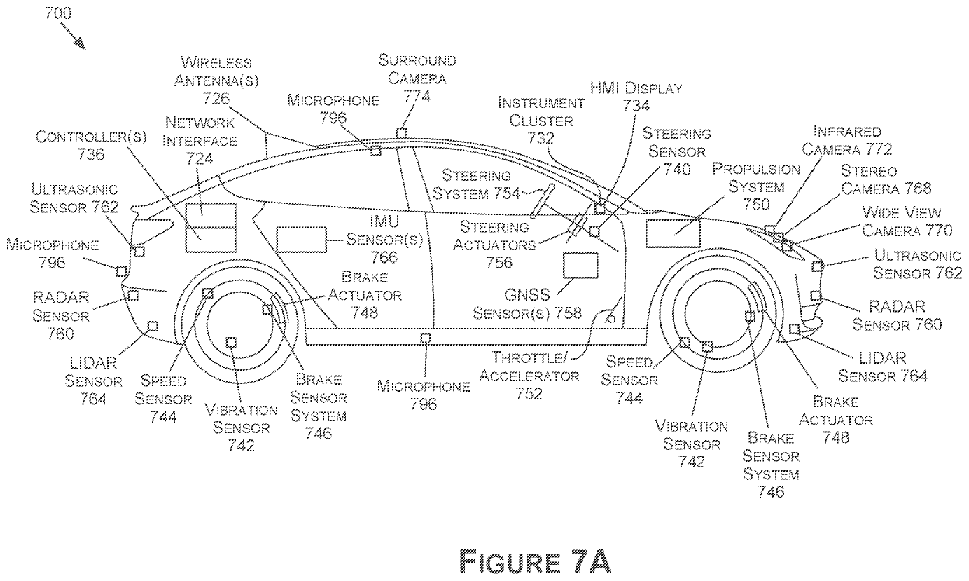

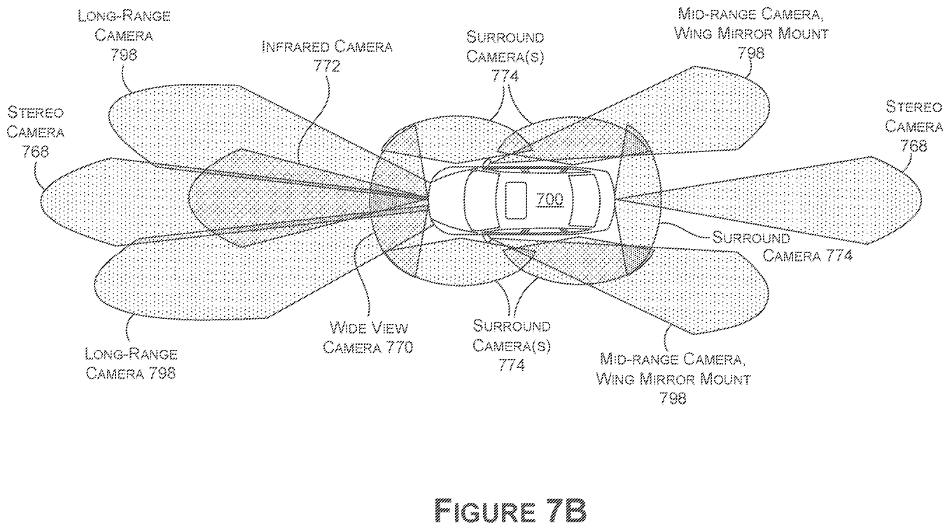

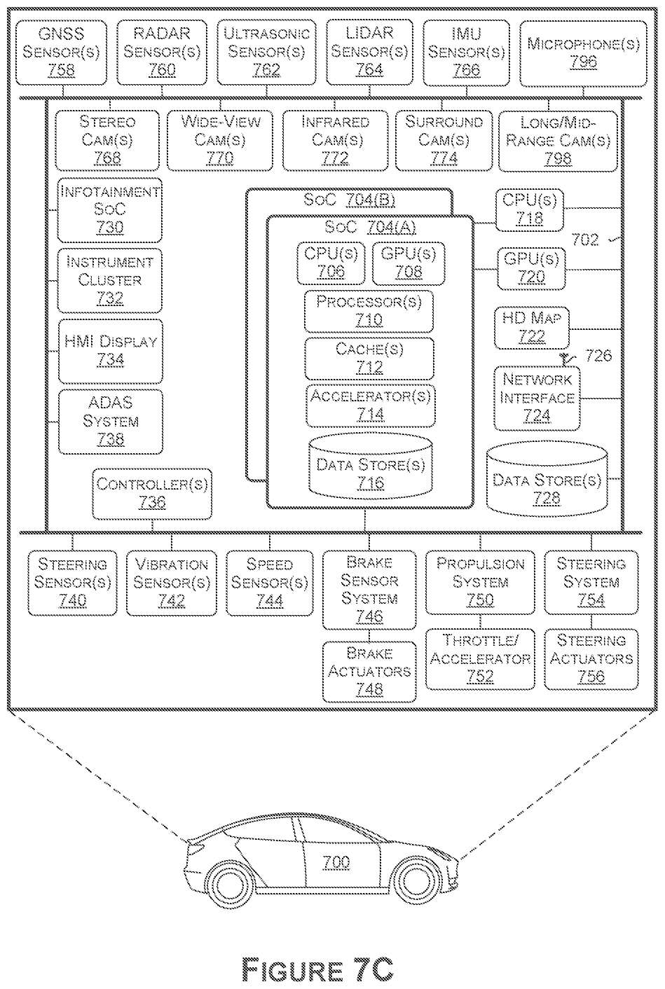

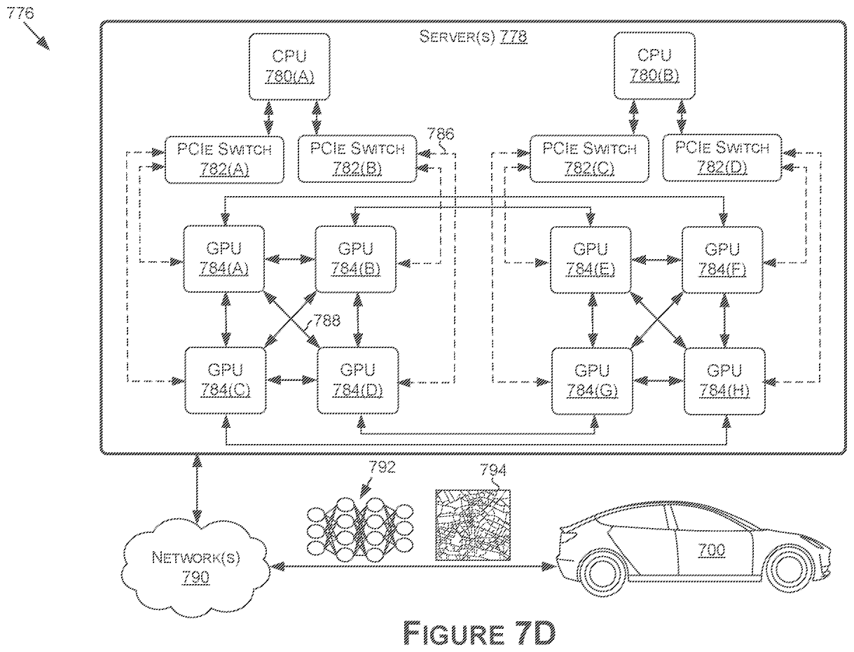

FIG. 7A is an illustration of an example autonomous vehicle 700, in accordance with some embodiments of the present disclosure. The autonomous vehicle 700 (alternatively referred to herein as the “vehicle 700”) may include, without limitation, a passenger vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a drone, and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 700 may be capable of functionality in accordance with one or more of Level 3-Level 5 of the autonomous driving levels. For example, the vehicle 700 may be capable of conditional automation (Level 3), high automation (Level 4), and/or full automation (Level 5), depending on the embodiment.

The vehicle 700 may include components such as a chassis, a vehicle body, wheels (e.g., 2, 4, 6, 8, 18, etc.), tires, axles, and other components of a vehicle. The vehicle 700 may include a propulsion system 750, such as an internal combustion engine, hybrid electric power plant, an all-electric engine, and/or another propulsion system type. The propulsion system 750 may be connected to a drive train of the vehicle 700, which may include a transmission, to enable the propulsion of the vehicle 700. The propulsion system 750 may be controlled in response to receiving signals from the throttle/accelerator 752.

A steering system 754, which may include a steering wheel, may be used to steer the vehicle 700 (e.g., along a desired path or route) when the propulsion system 750 is operating (e.g., when the vehicle is in motion). The steering system 754 may receive signals from a steering actuator 756. The steering wheel may be optional for full automation (Level 5) functionality.

The brake sensor system 746 may be used to operate the vehicle brakes in response to receiving signals from the brake actuators 748 and/or brake sensors.

Controller(s) 736, which may include one or more CPU(s), system on chips (SoCs) 704 (FIG. 7C) and/or GPU(s), may provide signals (e.g., representative of commands) to one or more components and/or systems of the vehicle 700. For example, the controller(s) may send signals to operate the vehicle brakes via one or more brake actuators 748, to operate the steering system 754 via one or more steering actuators 756, and/or to operate the propulsion system 750 via one or more throttle/accelerators 752. The controller(s) 736 may include one or more onboard (e.g., integrated) computing devices (e.g., supercomputers) that process sensor signals, and output operation commands (e.g., signals representing commands) to enable autonomous driving and/or to assist a human driver in driving the vehicle 700. The controller(s) 736 may include a first controller 736 for autonomous driving functions, a second controller 736 for functional safety functions, a third controller 736 for artificial intelligence functionality (e.g., computer vision), a fourth controller 736 for infotainment functionality, a fifth controller 736 for redundancy in emergency conditions, and/or other controllers. In some examples, a single controller 736 may handle two or more of the above functionalities, two or more controllers 736 may handle a single functionality, and/or any combination thereof.

The controller(s) 736 may provide the signals for controlling one or more components and/or systems of the vehicle 700 in response to sensor data received from one or more sensors (e.g., sensor inputs). The sensor data may be received from, for example and without limitation, global navigation satellite systems sensor(s) 758 (e.g., Global Positioning System sensor(s)), RADAR sensor(s) 760, ultrasonic sensor(s) 762, LIDAR sensor(s) 764, inertial measurement unit (IMU) sensor(s) 766 (e.g., accelerometer(s), gyroscope(s), magnetic compass(es), magnetometer(s), etc.), microphone(s) 796, stereo camera(s) 768, wide-view camera(s) 770 (e.g., fisheye cameras), infrared camera(s) 772, surround camera(s) 774 (e.g., 360 degree cameras), long-range and/or mid-range camera(s) 798, speed sensor(s) 744 (e.g., for measuring the speed of the vehicle 700), vibration sensor(s) 742, steering sensor(s) 740, brake sensor(s) 746 (e.g., as part of the brake sensor system 746), and/or other sensor types.

One or more of the controller(s) 736 may receive inputs (e.g., represented by input data) from an instrument cluster 732 of the vehicle 700 and provide outputs (e.g., represented by output data, display data, etc.) via a human-machine interface (HMI) display 734, an audible annunciator, a loudspeaker, and/or via other components of the vehicle 700. The outputs may include information such as vehicle velocity, speed, time, map data (e.g., the HD map 722 of FIG. 7C), location data (e.g., the location of the vehicle 700, such as on a map), direction, location of other vehicles (e.g., an occupancy grid), information about objects and status of objects as perceived by the controller(s) 736, etc. For example, the HMI display 734 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 700 further includes a network interface 724, which may use one or more wireless antenna(s) 726 and/or modem(s) to communicate over one or more networks. For example, the network interface 724 may be capable of communication over LTE, WCDMA, UMTS, GSM, CDMA2000, etc. The wireless antenna(s) 726 may also enable communication between objects in the environment (e.g., vehicles, mobile devices, etc.), using local area network(s), such as Bluetooth, Bluetooth LE, Z-Wave, ZigBee, etc., and/or low power wide-area network(s) (LPWANs), such as LoRaWAN, SigFox, etc.

FIG. 7B is an example of camera locations and fields of view for the example autonomous vehicle 700 of FIG. 7A, in accordance with some embodiments of the present disclosure. The cameras and respective fields of view are one example embodiment and are not intended to be limiting. For example, additional and/or alternative cameras may be included and/or the cameras may be located at different locations on the vehicle 700.

The camera types for the cameras may include, but are not limited to, digital cameras that may be adapted for use with the components and/or systems of the vehicle 700. The camera(s) may operate at automotive safety integrity level (ASIL) B and/or at another ASIL. The camera types may be capable of any image capture rate, such as 60 frames per second (fps), 120 fps, 240fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom-designed (3-D printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3-D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that includes portions of the environment in front of the vehicle 700 (e.g., front-facing cameras) may be used for surround view, to help identify forward-facing paths and obstacles, as well aid in, with the help of one or more controllers 736 and/or control SoCs, providing information critical to generating an occupancy grid and/or determining the preferred vehicle paths. Front-facing cameras may be used to perform many of the same ADAS functions as LIDAR, including emergency braking, pedestrian detection, and collision avoidance. Front-facing cameras may also be used for ADAS functions and systems including Lane Departure Warnings (LDW), Autonomous Cruise Control (ACC), and/or other functions such as traffic sign recognition.

A variety of cameras may be used in a front-facing configuration, including, for example, a monocular camera platform that includes a CMOS (complementary metal oxide semiconductor) color imager. Another example may be a wide-view camera(s) 770 that may be used to perceive objects coming into view from the periphery (e.g., pedestrians, crossing traffic or bicycles). Although only one wide-view camera is illustrated in FIG. 7B, there may any number of wide-view cameras 770 on the vehicle 700. In addition, long-range camera(s) 798 (e.g., a long-view stereo camera pair) may be used for depth-based object detection, especially for objects for which a neural network has not yet been trained. The long-range camera(s) 798 may also be used for object detection and classification, as well as basic object tracking.

One or more stereo cameras 768 may also be included in a front-facing configuration. The stereo camera(s) 768 may include an integrated control unit comprising a scalable processing unit, which may provide a programmable logic (e.g., FPGA) and a multi-core micro-processor with an integrated CAN or Ethernet interface on a single chip. Such a unit may be used to generate a 3-D map of the vehicle's environment, including a distance estimate for all the points in the image. An alternative stereo camera(s) 768 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 768 may be used in addition to, or alternatively from, those described herein.

Cameras with a field of view that includes portions of the environment to the side of the vehicle 700 (e.g., side-view cameras) may be used for surround view, providing information used to create and update the occupancy grid, as well as to generate side impact collision warnings. For example, surround camera(s) 774 (e.g., four surround cameras 774 as illustrated in FIG. 7B) may be positioned around the vehicle 700. The surround camera(s) 774 may include wide-view camera(s) 770, fisheye camera(s), 360-degree camera(s), and/or the like. For example, four fisheye cameras may be positioned on the vehicle's front, rear, and sides. In an alternative arrangement, the vehicle may use three surround camera(s) 774 (e.g., left, right, and rear), and may leverage one or more other camera(s) (e.g., a forward-facing camera) as a fourth surround-view camera.

Cameras with a field of view that include portions of the environment to the rear of the vehicle 700 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 798, stereo camera(s) 768), infrared camera(s) 772, etc.), as described herein.

FIG. 7C is a block diagram of an example system architecture for the example autonomous vehicle 700 of FIG. 7A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 700 in FIG. 7C is illustrated as being connected via bus 702. The bus 702 may include a Controller Area Network (CAN) data interface (alternatively referred to herein as a “CAN bus”). A CAN may be a network inside the vehicle 700 used to aid in control of various features and functionality of the vehicle 700, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 702 is described herein as being a CAN bus, this is not intended to be limiting. For example, in addition to, or alternatively from, the CAN bus, FlexRay and/or Ethernet may be used. Additionally, although a single line is used to represent the bus 702, this is not intended to be limiting. For example, there may be any number of busses 702, which may include one or more CAN busses, one or more FlexRay busses, one or more Ethernet busses, and/or one or more other types of busses using a different protocol. In some examples, two or more busses 702 may be used to perform different functions, and/or may be used for redundancy. For example, a first bus 702 may be used for collision avoidance functionality and a second bus 702 may be used for actuation control. In any example, each bus 702 may communicate with any of the components of the vehicle 700, and two or more busses 702 may communicate with the same components. In some examples, each SoC 704, each controller 736, and/or each computer within the vehicle may have access to the same input data (e.g., inputs from sensors of the vehicle 700), and may be connected to a common bus, such the CAN bus.

The vehicle 700 may include one or more controller(s) 736, such as those described herein with respect to FIG. 7A. The controller(s) 736 may be used for a variety of functions. The controller(s) 736 may be coupled to any of the various other components and systems of the vehicle 700 and may be used for control of the vehicle 700, artificial intelligence of the vehicle 700, infotainment for the vehicle 700, and/or the like.

The vehicle 700 may include a system(s) on a chip (SoC) 704. The SoC 704 may include CPU(s) 706, GPU(s) 708, processor(s) 710, cache(s) 712, accelerator(s) 714, data store(s) 716, and/or other components and features not illustrated. The SoC(s) 704 may be used to control the vehicle 700 in a variety of platforms and systems. For example, the SoC(s) 704 may be combined in a system (e.g., the system of the vehicle 700) with an HD map 722 which may obtain map refreshes and/or updates via a network interface 724 from one or more servers (e.g., server(s) 778 of FIG. 7D).

The CPU(s) 706 may include a CPU cluster or CPU complex (alternatively referred to herein as a “CCPLEX”). The CPU(s) 706 may include multiple cores and/or L2 caches. For example, in some embodiments, the CPU(s) 706 may include eight cores in a coherent multi-processor configuration. In some embodiments, the CPU(s) 706 may include four dual-core clusters where each cluster has a dedicated L2 cache (e.g., a 2 MB L2 cache). The CPU(s) 706 (e.g., the CCPLEX) may be configured to support simultaneous cluster operation enabling any combination of the clusters of the CPU(s) 706 to be active at any given time.

The CPU(s) 706 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 706 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 708 may include an integrated GPU (alternatively referred to herein as an “iGPU”). The GPU(s) 708 may be programmable and may be efficient for parallel workloads. The GPU(s) 708, in some examples, may use an enhanced tensor instruction set. The GPU(s) 708 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 708 may include at least eight streaming microprocessors. The GPU(s) 708 may use computer-based application programming interface(s) (API(s)). In addition, the GPU(s) 708 may use one or more parallel computing platforms and/or programming models (e.g., NVIDIA's CUDA).

The GPU(s) 708 may be power-optimized for best performance in automotive and embedded use cases. For example, the GPU(s) 708 may be fabricated on a Fin field-effect transistor (FinFET). However, this is not intended to be limiting, and the GPU(s) 708 may be fabricated using other semiconductor manufacturing processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an LO instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread-scheduling capability to enable finer-grain synchronization and cooperation between parallel threads. The streaming microprocessors may include a combined LI data cache and shared memory unit in order to improve performance while simplifying programming.

The GPU(s) 708 may include a high bandwidth memory (HBM) and/or a 16 GB HBM2 memory subsystem to provide, in some examples, about 900 GB/second peak memory bandwidth.

In some examples, in addition to, or alternatively from, the HBM memory, a synchronous graphics random-access memory (SGRAM) may be used, such as a graphics double data rate type five synchronous random-access memory (GDDR5).

The GPU(s) 708 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 708 to access the CPU(s) 706 page tables directly. In such examples, when the GPU(s) 708 memory management unit (MMU) experiences a miss, an address translation request may be transmitted to the CPU(s) 706. In response, the CPU(s) 706 may look in its page tables for the virtual-to-physical mapping for the address and transmits the translation back to the GPU(s) 708. As such, unified memory technology may allow a single unified virtual address space for memory of both the CPU(s) 706 and the GPU(s) 708, thereby simplifying the GPU(s) 708 programming and porting of applications to the GPU(s) 708.

In addition, the GPU(s) 708 may include an access counter that may keep track of the frequency of access of the GPU(s) 708 to memory of other processors. The access counter may help ensure that memory pages are moved to the physical memory of the processor that is accessing the pages most frequently.

The SoC(s) 704 may include any number of cache(s) 712, including those described herein. For example, the cache(s) 712 may include an L3 cache that is available to both the CPU(s) 706 and the GPU(s) 708 (e.g., that is connected to both the CPU(s) 706 and the GPU(s) 708). The cache(s) 712 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 704 may include an arithmetic logic unit(s) (ALU(s)) which may be leveraged in performing processing with respect to any of the variety of tasks or operations of the vehicle 700—such as processing DNNs. In addition, the SoC(s) 704 may include a floating point unit(s) (FPU(s))—or other math coprocessor or numeric coprocessor types-for performing mathematical operations within the system. For example, the SoC(s) 704 may include one or more FPUs integrated as execution units within a CPU(s) 706 and/or GPU(s) 708.

The SoC(s) 704 may include one or more accelerators 714 (e.g., hardware accelerators, software accelerators, or a combination thereof). For example, the SoC(s) 704 may include a hardware acceleration cluster that may include optimized hardware accelerators and/or large on-chip memory. The large on-chip memory (e.g., 4 MB of SRAM), may enable the hardware acceleration cluster to accelerate neural networks and other calculations. The hardware acceleration cluster may be used to complement the GPU(s) 708 and to off-load some of the tasks of the GPU(s) 708 (e.g., to free up more cycles of the GPU(s) 708 for performing other tasks). As an example, the accelerator(s) 714 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 714 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

The DLA(s) may perform any function of the GPU(s) 708, and by using an inference accelerator, for example, a designer may target either the DLA(s) or the GPU(s) 708 for any function. For example, the designer may focus processing of CNNs and floating point operations on the DLA(s) and leave other functions to the GPU(s) 708 and/or other accelerator(s) 714.

The accelerator(s) 714 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may enable components of the PVA(s) to access the system memory independently of the CPU(s) 706. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 714 (e.g., the hardware acceleration cluster) may include a computer vision network on-chip and SRAM, for providing a high-bandwidth, low latency SRAM for the accelerator(s) 714. In some examples, the on-chip memory may include at least 4 MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 704 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses. In some embodiments, one or more tree traversal units (TTUs) may be used for executing one or more ray-tracing related operations.

The accelerator(s) 714 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. In other words, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. For example, the PVA may be used to process raw RADAR data (e.g., using a 4D Fast Fourier Transform) to provide a processed RADAR signal before emitting the next RADAR pulse. In other examples, the PVA is used for time of flight depth processing, by processing raw time of flight data to provide processed time of flight data, for example.

The DLA may be used to run any type of network to enhance control and driving safety, including, for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding box dimensions, ground plane estimate obtained (e.g. from another subsystem), inertial measurement unit (IMU) sensor 766 output that correlates with the vehicle 700 orientation, distance, 3D location estimates of the object obtained from the neural network and/or other sensors (e.g., LIDAR sensor(s) 764 or RADAR sensor(s) 760), among others.

The SoC(s) 704 may include data store(s) 716 (e.g., memory). The data store(s) 716 may be on-chip memory of the SoC(s) 704, which may store neural networks to be executed on the GPU and/or the DLA. In some examples, the data store(s) 716 may be large enough in capacity to store multiple instances of neural networks for redundancy and safety. The data store(s) 716 may comprise L2 or L3 cache(s) 712. Reference to the data store(s) 716 may include reference to the memory associated with the PVA, DLA, and/or other accelerator(s) 714, as described herein.

The SoC(s) 704 may include one or more processor(s) 710 (e.g., embedded processors). The processor(s) 710 may include a boot and power management processor that may be a dedicated processor and subsystem to handle boot power and management functions and related security enforcement. The boot and power management processor may be a part of the SoC(s) 704 boot sequence and may provide runtime power management services. The boot power and management processor may provide clock and voltage programming, assistance in system low power state transitions, management of SoC(s) 704 thermals and temperature sensors, and/or management of the SoC(s) 704 power states. Each temperature sensor may be implemented as a ring-oscillator whose output frequency is proportional to temperature, and the SoC(s) 704 may use the ring-oscillators to detect temperatures of the CPU(s) 706, GPU(s) 708, and/or accelerator(s) 714. If temperatures are determined to exceed a threshold, the boot and power management processor may enter a temperature fault routine and put the SoC(s) 704 into a lower power state and/or put the vehicle 700 into a chauffeur to safe-stop mode (e.g., bring the vehicle 700 to a safe stop).

The processor(s) 710 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 710 may further include an always-on processor engine that may provide necessary hardware features to support low power sensor management and wake use cases. The always-on processor engine may include a processor core, a tightly coupled RAM, supporting peripherals (e.g., timers and interrupt controllers), various I/O controller peripherals, and routing logic.

The processor(s) 710 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 710 may further include a real-time camera engine that may include a dedicated processor subsystem for handling real-time camera management.

The processor(s) 710 may further include a high dynamic range signal processor that may include an image signal processor that is a hardware engine that is part of the camera processing pipeline.

The processor(s) 710 may include a video image compositor that may be a processing block (e.g., implemented on a microprocessor) that implements video post-processing functions needed by a video playback application to produce the final image for the player window. The video image compositor may perform lens distortion correction on wide-view camera(s) 770, surround camera(s) 774, and/or on in-cabin monitoring camera sensors. An in-cabin monitoring camera sensor is preferably monitored by a neural network running on another instance of the advanced SoC, configured to identify in-cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 708 is not required to continuously render new surfaces. Even when the GPU(s) 708 is powered on and actively performing 3D rendering, the video image compositor may be used to offload the GPU(s) 708 to improve performance and responsiveness.

The SoC(s) 704 may further include a mobile industry processor interface (MIPI) camera serial interface for receiving video and input from cameras, a high-speed interface, and/or a video input block that may be used for camera and related pixel input functions. The SoC(s) 704 may further include an input/output controller(s) that may be controlled by software and may be used for receiving I/O signals that are uncommitted to a specific role.

The SoC(s) 704 may further include a broad range of peripheral interfaces to enable communication with peripherals, audio codecs, power management, and/or other devices. The SoC(s) 704 may be used to process data from cameras (e.g., connected over Gigabit Multimedia Serial Link and Ethernet), sensors (e.g., LIDAR sensor(s) 764, RADAR sensor(s) 760, etc. that may be connected over Ethernet), data from bus 702 (e.g., speed of vehicle 700, steering wheel position, etc.), data from GNSS sensor(s) 758 (e.g., connected over Ethernet or CAN bus). The SoC(s) 704 may further include dedicated high-performance mass storage controllers that may include their own DMA engines, and that may be used to free the CPU(s) 706 from routine data management tasks.

The SoC(s) 704 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 704 may be faster, more reliable, and even more energy-efficient and space-efficient than conventional systems. For example, the accelerator(s) 714, when combined with the CPU(s) 706, the GPU(s) 708, and the data store(s) 716, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks to be performed simultaneously and/or sequentially, and for the results to be combined together to enable Level 3-5 autonomous driving functionality. For example, a CNN executing on the DLA or dGPU (e.g., the GPU(s) 720) may include a text and word recognition, allowing the supercomputer to read and understand traffic signs, including signs for which the neural network has not been specifically trained. The DLA may further include a neural network that is able to identify, interpret, and provide semantic understanding of the sign, and to pass that semantic understanding to the path-planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path-planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 708.

In some examples, a CNN for facial recognition and vehicle owner identification may use data from camera sensors to identify the presence of an authorized driver and/or owner of the vehicle 700. The always-on sensor processing engine may be used to unlock the vehicle when the owner approaches the driver door and turn on the lights, and, in security mode, to disable the vehicle when the owner leaves the vehicle. In this way, the SoC(s) 704 provide for security against theft and/or carjacking.

In another example, a CNN for emergency vehicle detection and identification may use data from microphones 796 to detect and identify emergency vehicle sirens. In contrast to conventional systems, which use general classifiers to detect sirens and manually extract features, the SoC(s) 704 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 758. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 762, until the emergency vehicle(s) passes.

The vehicle may include a CPU(s) 718 (e.g., discrete CPU(s), or dCPU(s)), that may be coupled to the SoC(s) 704 via a high-speed interconnect (e.g., PCIe). The CPU(s) 718 may include an X86 processor, for example. The CPU(s) 718 may be used to perform any of a variety of functions, including arbitrating potentially inconsistent results between ADAS sensors and the SoC(s) 704, and/or monitoring the status and health of the controller(s) 736 and/or infotainment SoC 730, for example.

The vehicle 700 may include a GPU(s) 720 (e.g., discrete GPU(s), or dGPU(s)), that may be coupled to the SoC(s) 704 via a high-speed interconnect (e.g., NVIDIA's NVLINK). The GPU(s) 720 may provide additional artificial intelligence functionality, such as by executing redundant and/or different neural networks, and may be used to train and/or update neural networks based on input (e.g., sensor data) from sensors of the vehicle 700.

The vehicle 700 may further include the network interface 724 which may include one or more wireless antennas 726 (e.g., one or more wireless antennas for different communication protocols, such as a cellular antenna, a Bluetooth antenna, etc.). The network interface 724 may be used to enable wireless connectivity over the Internet with the cloud (e.g., with the server(s) 778 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 700 information about vehicles in proximity to the vehicle 700 (e.g., vehicles in front of, on the side of, and/or behind the vehicle 700). This functionality may be part of a cooperative adaptive cruise control functionality of the vehicle 700.

The network interface 724 may include an SoC that provides modulation and demodulation functionality and enables the controller(s) 736 to communicate over wireless networks. The network interface 724 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 700 may further include data store(s) 728, which may include off-chip (e.g., off the SoC(s) 704) storage. The data store(s) 728 may include one or more storage elements including RAM, SRAM, DRAM, VRAM, Flash, hard disks, and/or other components and/or devices that may store at least one bit of data.

The vehicle 700 may further include GNSS sensor(s) 758 (e.g., GPS and/or assisted GPS sensors), to assist in mapping, perception, occupancy grid generation, and/or path planning functions. Any number of GNSS sensor(s) 758 may be used, including, for example and without limitation, a GPS using a USB connector with an Ethernet to serial (RS-232) bridge.

The vehicle 700 may further include RADAR sensor(s) 760. The RADAR sensor(s) 760 may be used by the vehicle 700 for long-range vehicle detection, even in darkness and/or severe weather conditions. RADAR functional safety levels may be ASIL B. The RADAR sensor(s) 760 may use the CAN and/or the bus 702 (e.g., to transmit data generated by the RADAR sensor(s) 760) for control and to access object tracking data, with access to Ethernet to access raw data, in some examples. A wide variety of RADAR sensor types may be used. For example, and without limitation, the RADAR sensor(s) 760 may be suitable for front, rear, and side RADAR use. In some example, Pulse Doppler RADAR sensor(s) are used.

The RADAR sensor(s) 760 may include different configurations, such as long-range with narrow field of view, short-range with wide field of view, short-range side coverage, etc. In some examples, long-range RADAR may be used for adaptive cruise control functionality. The long-range RADAR systems may provide a broad field of view realized by two or more independent scans, such as within a 250 m range. The RADAR sensor(s) 760 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the surrounding of the vehicle 700 at higher speeds with minimal interference from traffic in adjacent lanes. The other two antennae may expand the field of view, making it possible to quickly detect vehicles entering or leaving the vehicle's 700 lane.

Mid-range RADAR systems may include, as an example, a range of up to 760 m (front) or 80 m (rear), and a field of view of up to 42 degrees (front) or 750 degrees (rear). Short-range RADAR systems may include, without limitation, RADAR sensors designed to be installed at both ends of the rear bumper. When installed at both ends of the rear bumper, such a RADAR sensor system may create two beams that constantly monitor the blind spot in the rear and next to the vehicle.

Short-range RADAR systems may be used in an ADAS system for blind spot detection and/or lane change assist.

The vehicle 700 may further include ultrasonic sensor(s) 762. The ultrasonic sensor(s) 762, which may be positioned at the front, back, and/or the sides of the vehicle 700, may be used for park assist and/or to create and update an occupancy grid. A wide variety of ultrasonic sensor(s) 762 may be used, and different ultrasonic sensor(s) 762 may be used for different ranges of detection (e.g., 2.5 m, 4 m). The ultrasonic sensor(s) 762 may operate at functional safety levels of ASIL B.

The vehicle 700 may include LIDAR sensor(s) 764. The LIDAR sensor(s) 764 may be used for object and pedestrian detection, emergency braking, collision avoidance, and/or other functions. The LIDAR sensor(s) 764 may be functional safety level ASIL B. In some examples, the vehicle 700 may include multiple LIDAR sensors 764 (e.g., two, four, six, etc.) that may use Ethernet (e.g., to provide data to a Gigabit Ethernet switch).

In some examples, the LIDAR sensor(s) 764 may be capable of providing a list of objects and their distances for a 360-degree field of view. Commercially available LIDAR sensor(s) 764 may have an advertised range of approximately 100 m, with an accuracy of 2 cm-3 cm, and with support for a 100 Mbps Ethernet connection, for example. In some examples, one or more non-protruding LIDAR sensors 764 may be used. In such examples, the LIDAR sensor(s) 764 may be implemented as a small device that may be embedded into the front, rear, sides, and/or corners of the vehicle 700. The LIDAR sensor(s) 764, in such examples, may provide up to a 120-degree horizontal and 35-degree vertical field-of-view, with a 200 m range even for low-reflectivity objects. Front-mounted LIDAR sensor(s) 764 may be configured for a horizontal field of view between 45 degrees and 135 degrees.

In some examples, LIDAR technologies, such as 3D flash LIDAR, may also be used. 3D Flash LIDAR uses a flash of a laser as a transmission source, to illuminate vehicle surroundings up to approximately 200m. A flash LIDAR unit includes a receptor, which records the laser pulse transit time and the reflected light on each pixel, which in turn corresponds to the range from the vehicle to the objects. Flash LIDAR may allow for highly accurate and distortion-free images of the surroundings to be generated with every laser flash. In some examples, four flash LIDAR sensors may be deployed, one at each side of the vehicle 700. Available 3D flash LIDAR systems include a solid-state 3D staring array LIDAR camera with no moving parts other than a fan (e.g., a non-scanning LIDAR device). The flash LIDAR device may use a five nanosecond class I (eye-safe) laser pulse per frame and may capture the reflected laser light in the form of 3D range point clouds and co-registered intensity data. By using flash LIDAR, and because flash LIDAR is a solid-state device with no moving parts, the LIDAR sensor(s) 764 may be less susceptible to motion blur, vibration, and/or shock.

The vehicle may further include IMU sensor(s) 766. The IMU sensor(s) 766 may be located at a center of the rear axle of the vehicle 700, in some examples. The IMU sensor(s) 766 may include, for example and without limitation, an accelerometer(s), a magnetometer(s), a gyroscope(s), a magnetic compass(es), and/or other sensor types. In some examples, such as in six-axis applications, the IMU sensor(s) 766 may include accelerometers and gyroscopes, while in nine-axis applications, the IMU sensor(s) 766 may include accelerometers, gyroscopes, and magnetometers.

In some embodiments, the IMU sensor(s) 766 may be implemented as a miniature, high-performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 766 may enable the vehicle 700 to estimate heading without requiring input from a magnetic sensor by directly observing and correlating the changes in velocity from GPS to the IMU sensor(s) 766. In some examples, the IMU sensor(s) 766 and the GNSS sensor(s) 758 may be combined in a single integrated unit.

The vehicle may include microphone(s) 796 placed in and/or around the vehicle 700. The microphone(s) 796 may be used for emergency vehicle detection and identification, among other things.

The vehicle may further include any number of camera types, including stereo camera(s) 768, wide-view camera(s) 770, infrared camera(s) 772, surround camera(s) 774, long-range and/or mid-range camera(s) 798, and/or other camera types. The cameras may be used to capture image data around an entire periphery of the vehicle 700. The types of cameras used depends on the embodiments and requirements for the vehicle 700, and any combination of camera types may be used to provide the necessary coverage around the vehicle 700. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 7A and FIG. 7B.

The vehicle 700 may further include vibration sensor(s) 742. The vibration sensor(s) 742 may measure vibrations of components of the vehicle, such as the axle(s). For example, changes in vibrations may indicate a change in road surfaces. In another example, when two or more vibration sensors 742 are used, the differences between the vibrations may be used to determine friction or slippage of the road surface (e.g., when the difference in vibration is between a power-driven axle and a freely rotating axle).

The vehicle 700 may include an ADAS system 738. The ADAS system 738 may include an SoC, in some examples. The ADAS system 738 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 760, LIDAR sensor(s) 764, and/or a camera(s). The ACC systems may include longitudinal ACC and/or lateral ACC. Longitudinal ACC monitors and controls the distance to the vehicle immediately ahead of the vehicle 700 and automatically adjusts the vehicle speed to maintain a safe distance from vehicles ahead. Lateral ACC performs distance keeping, and advises the vehicle 700 to change lanes when necessary. Lateral ACC is related to other ADAS applications such as LC and CWS.

CACC uses information from other vehicles that may be received via the network interface 724 and/or the wireless antenna(s) 726 from other vehicles via a wireless link, or indirectly, over a network connection (e.g., over the Internet). Direct links may be provided by a vehicle-to-vehicle (V2V) communication link, while indirect links may be infrastructure-to-vehicle (I2V) communication links. In general, the V2V communication concept provides information about the immediately preceding vehicles (e.g., vehicles immediately ahead of and in the same lane as the vehicle 700), while the I2V communication concept provides information about traffic farther ahead. CACC systems may include either or both I2V and V2V information sources. Given the information of the vehicles ahead of the vehicle 700, CACC may be more reliable, and it has potential to improve traffic flow smoothness and reduce congestion on the road.

FCW systems are designed to alert the driver to a hazard, so that the driver may take corrective action. FCW systems use a front-facing camera and/or RADAR sensor(s) 760, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 760, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 700 crosses lane markings. An LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 700 if the vehicle 700 starts to exit the lane.

BSW systems detect and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 760, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 700 is backing up. Some RCTW systems include AEB to ensure that the vehicle brakes are applied to avoid a crash. RCTW systems may use one or more rear-facing RADAR sensor(s) 760, coupled to a dedicated processor, DSP, FPGA, and/or ASIC, that is electrically coupled to driver feedback, such as a display, speaker, and/or vibrating component.

Conventional ADAS systems may be prone to false positive results, which may be annoying and distracting to a driver, but typically are not catastrophic, because the ADAS systems alert the driver and allow the driver to decide whether a safety condition truly exists and act accordingly. However, in an autonomous vehicle 700, the vehicle 700 itself must, in the case of conflicting results, decide whether to heed the result from a primary computer or a secondary computer (e.g., a first controller 736 or a second controller 736). For example, in some embodiments, the ADAS system 738 may be a backup and/or secondary computer for providing perception information to a backup computer rationality module. The backup computer rationality monitor may run a redundant diverse software on hardware components to detect faults in perception and dynamic driving tasks. Outputs from the ADAS system 738 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output can be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 704.

In other examples, ADAS system 738 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity make the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware used by the primary computer is not causing material error.

In some examples, the output of the ADAS system 738 may be fed into the primary computer's perception block and/or the primary computer's dynamic driving task block. For example, if the ADAS system 738 indicates a forward crash warning due to an object immediately ahead, the perception block may use this information when identifying objects. In other examples, the secondary computer may have its own neural network that is trained and thus reduces the risk of false positives, as described herein.

The vehicle 700 may further include the infotainment SoC 730 (e.g., an in-vehicle infotainment system (IVI)). Although illustrated and described as an SoC, the infotainment system may not be a SoC, and may include two or more discrete components. The infotainment SoC 730 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle-related information such as fuel level, total distance covered, brake fuel level, oil level, door open/close, air filter information, etc.) to the vehicle 700. For example, the infotainment SoC 730 may include radios, disk players, navigation systems, video players, USB and Bluetooth connectivity, carputers, in-car entertainment, Wi-Fi, steering wheel audio controls, hands-free voice control, a heads-up display (HUD), an HMI display 734, a telematics device, a control panel (e.g., for controlling and/or interacting with various components, features, and/or systems), and/or other components. The infotainment SoC 730 may further be used to provide information (e.g., visual and/or audible) to a user(s) of the vehicle, such as information from the ADAS system 738, autonomous driving information such as planned vehicle maneuvers, trajectories, surrounding environment information (e.g., intersection information, vehicle information, road information, etc.), and/or other information.

The infotainment SoC 730 may include GPU functionality. The infotainment SoC 730 may communicate over the bus 702 (e.g., CAN bus, Ethernet, etc.) with other devices, systems, and/or components of the vehicle 700. In some examples, the infotainment SoC 730 may be coupled to a supervisory MCU such that the GPU of the infotainment system may perform some self-driving functions in the event that the primary controller(s) 736 (e.g., the primary and/or backup computers of the vehicle 700) fail. In such an example, the infotainment SoC 730 may put the vehicle 700 into a chauffeur to safe-stop mode, as described herein.

The vehicle 700 may further include an instrument cluster 732 (e.g., a digital dash, an electronic instrument cluster, a digital instrument panel, etc.). The instrument cluster 732 may include a controller and/or supercomputer (e.g., a discrete controller or supercomputer). The instrument cluster 732 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 730 and the instrument cluster 732. In other words, the instrument cluster 732 may be included as part of the infotainment SoC 730, or vice versa.

FIG. 7D is a system diagram for communication between cloud-based server(s) and the example autonomous vehicle 700 of FIG. 7A, in accordance with some embodiments of the present disclosure. The system 776 may include server(s) 778, network(s) 790, and vehicles, including the vehicle 700. The server(s) 778 may include a plurality of GPUs 784 (A)-784 (H) (collectively referred to herein as GPUs 784), PCIe switches 782 (A)-782 (H) (collectively referred to herein as PCle switches 782), and/or CPUs 780 (A)-780 (B) (collectively referred to herein as CPUs 780).

The GPUs 784, the CPUs 780, and the PCle switches may be interconnected with high-speed interconnects such as, for example and without limitation, NVLink interfaces 788 developed by NVIDIA and/or PCIe connections 786. In some examples, the GPUs 784 are connected via NVLink and/or NVSwitch SoC and the GPUs 784 and the PCle switches 782 are connected via PCIe interconnects. Although eight GPUs 784, two CPUs 780, and two PCle switches are illustrated, this is not intended to be limiting. Depending on the embodiment, each of the server(s) 778 may include any number of GPUs 784, CPUs 780, and/or PCIe switches. For example, the server(s) 778 may each include eight, sixteen, thirty-two, and/or more GPUs 784.

The server(s) 778 may receive, over the network(s) 790 and from the vehicles, image data representative of images showing unexpected or changed road conditions, such as recently commenced roadwork. The server(s) 778 may transmit, over the network(s) 790 and to the vehicles, neural networks 792, updated neural networks 792, and/or map information 794, including information regarding traffic and road conditions. The updates to the map information 794 may include updates for the HD map 722, such as information regarding construction sites, potholes, detours, flooding, and/or other obstructions. In some examples, the neural networks 792, the updated neural networks 792, and/or the map information 794 may have resulted from new training and/or experiences represented in data received from any number of vehicles in the environment, and/or based on training performed at a datacenter (e.g., using the server(s) 778 and/or other servers).

The server(s) 778 may be used to train machine learning models (e.g., neural networks) based on training data. The training data may be generated by the vehicles, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 790, and/or the machine learning models may be used by the server(s) 778 to remotely monitor the vehicles.

In some examples, the server(s) 778 may receive data from the vehicles and apply the data to up-to-date real-time neural networks for real-time intelligent inferencing. The server(s) 778 may include deep-learning supercomputers and/or dedicated AI computers powered by GPU(s) 784, such as a DGX and DGX Station machines developed by NVIDIA. However, in some examples, the server(s) 778 may include deep learning infrastructure that use only CPU-powered datacenters.

The deep-learning infrastructure of the server(s) 778 may be capable of fast, real-time inferencing, and may use that capability to evaluate and verify the health of the processors, software, and/or associated hardware in the vehicle 700. For example, the deep-learning infrastructure may receive periodic updates from the vehicle 700, such as a sequence of images and/or objects that the vehicle 700 has located in that sequence of images (e.g., via computer vision and/or other machine learning object classification techniques). The deep-learning infrastructure may run its own neural network to identify the objects and compare them with the objects identified by the vehicle 700 and, if the results do not match and the infrastructure concludes that the AI in the vehicle 700 is malfunctioning, the server(s) 778 may transmit a signal to the vehicle 700 instructing a fail-safe computer of the vehicle 700 to assume control, notify the passengers, and complete a safe parking maneuver.

For inferencing, the server(s) 778 may include the GPU(s) 784 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

### EXAMPLE COMPUTING DEVICE

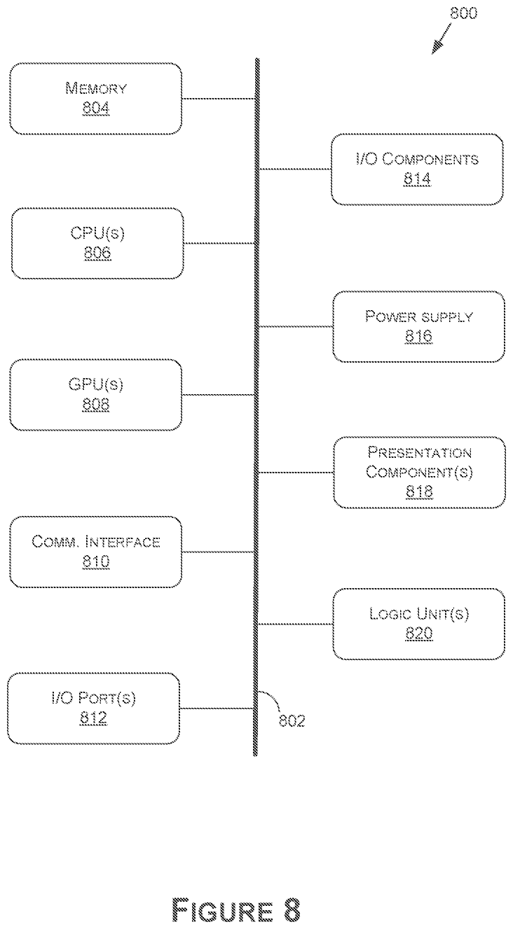

FIG. 8 is a block diagram of an example computing device(s) 800 suitable for use in implementing some embodiments of the present disclosure. Computing device 800 may include an interconnect system 802 that directly or indirectly couples the following devices: memory 804, one or more central processing units (CPUs) 806, one or more graphics processing units (GPUs) 808, a communication interface 810, I/O ports 812, input/output components 814, a power supply 816, one or more presentation components 818 (e.g., display(s)), and one or more logic units 820.

Although the various blocks of FIG. 8 are shown as connected via the interconnect system 802 with lines, this is not intended to be limiting and is for clarity only. For example, in some embodiments, a presentation component 818, such as a display device, may be considered an I/O component 814 (e.g., if the display is a touch screen). As another example, the CPUs 806 and/or GPUs 808 may include memory (e.g., the memory 804 may be representative of a storage device in addition to the memory of the GPUs 808, the CPUs 806, and/or other components). In other words, the computing device of FIG. 8 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” “augmented reality system,” and/or other device or system types, as all are contemplated within the scope of the computing device of FIG. 8.

The interconnect system 802 may represent one or more links or busses, such as an address bus, a data bus, a control bus, or a combination thereof. The interconnect system 802 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 806 may be directly connected to the memory 804. Further, the CPU 806 may be directly connected to the GPU 808. Where there is direct, or point-to-point, connection between components, the interconnect system 802 may include a PCIe link to carry out the connection. In these examples, a PCI bus need not be included in the computing device 800.

The memory 804 may include any of a variety of computer-readable media. The computer-readable media may be any available media that may be accessed by the computing device 800. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 804 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium that may be used to store the desired information and that may be accessed by computing device 800. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 806 may be configured to execute at least some of the computer-readable instructions to control one or more components of the computing device 800 to perform one or more of the methods and/or processes described herein. The CPU(s) 806 may each include one or more cores (e.g., one, two, four, eight, twenty-eight, seventy-two, etc.) that are capable of handling a multitude of software threads simultaneously. The CPU(s) 806 may include any type of processor, and may include different types of processors depending on the type of computing device 800 implemented (e.g., processors with fewer cores for mobile devices and processors with more cores for servers). For example, depending on the type of computing device 800, the processor may be an Advanced RISC Machines (ARM) processor implemented using Reduced Instruction Set Computing (RISC) or an x86 processor implemented using Complex Instruction Set Computing (CISC). The computing device 800 may include one or more CPUs 806 in addition to one or more microprocessors or supplementary co-processors, such as math co-processors.

In addition to or alternatively from the CPU(s) 806, the GPU(s) 808 may be configured to execute at least some of the computer-readable instructions to control one or more components of the computing device 800 to perform one or more of the methods and/or processes described herein. One or more of the GPU(s) 808 may be an integrated GPU (e.g., with one or more of the CPU(s) 806 and/or one or more of the GPU(s) 808 may be a discrete GPU. In embodiments, one or more of the GPU(s) 808 may be a coprocessor of one or more of the CPU(s) 806. The GPU(s) 808 may be used by the computing device 800 to render graphics (e.g., 3D graphics) or perform general purpose computations. For example, the GPU(s) 808 may be used for General-Purpose computing on GPUs (GPGPU). The GPU(s) 808 may include hundreds or thousands of cores that are capable of handling hundreds or thousands of software threads simultaneously. The GPU(s) 808 may generate pixel data for output images in response to rendering commands (e.g., rendering commands from the CPU(s) 806 received via a host interface). The GPU(s) 808 may include graphics memory, such as display memory, for storing pixel data or any other suitable data, such as GPGPU data. The display memory may be included as part of the memory 804. The GPU(s) 808 may include two or more GPUs operating in parallel (e.g., via a link). The link may directly connect the GPUs (e.g., using NVLINK) or may connect the GPUs through a switch (e.g., using NVSwitch). When combined together, each GPU 808 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 806 and/or the GPU(s) 808, the logic unit(s) 820 may be configured to execute at least some of the computer-readable instructions to control one or more components of the computing device 800 to perform one or more of the methods and/or processes described herein. In embodiments, the CPU(s) 806, the GPU(s) 808, and/or the logic unit(s) 820 may discretely or jointly perform any combination of the methods, processes and/or portions thereof. One or more of the logic units 820 may be part of and/or integrated in one or more of the CPU(s) 806 and/or the GPU(s) 808 and/or one or more of the logic units 820 may be discrete components or otherwise external to the CPU(s) 806 and/or the GPU(s) 808. In embodiments, one or more of the logic units 820 may be a coprocessor of one or more of the CPU(s) 806 and/or one or more of the GPU(s) 808.

Examples of the logic unit(s) 820 include one or more processing cores and/or components thereof, such as Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), I/O elements, peripheral component interconnect (PCI) or peripheral component interconnect express (PCIe) elements, and/or the like.

The communication interface 810 may include one or more receivers, transmitters, and/or transceivers that enable the computing device 800 to communicate with other computing devices via an electronic communication network, including wired and/or wireless communications. The communication interface 810 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet.

The I/O ports 812 may enable the computing device 800 to be logically coupled to other devices including the I/O components 814, the presentation component(s) 818, and/or other components, some of which may be built into (e.g., integrated in) the computing device 800. Illustrative I/O components 814 include a microphone, mouse, keyboard, joystick, game pad, game controller, satellite dish, scanner, printer, wireless device, etc. The I/O components 814 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 800. The computing device 800 may include depth cameras, such as stereoscopic camera systems, infrared camera systems, RGB camera systems, touchscreen technology, and combinations of these, for gesture detection and recognition. Additionally, the computing device 800 may include accelerometers or gyroscopes (e.g., as part of an inertia measurement unit (IMU)) that enable detection of motion. In some examples, the output of the accelerometers or gyroscopes may be used by the computing device 800 to render immersive augmented reality or virtual reality.

The power supply 816 may include a hard-wired power supply, a battery power supply, or a combination thereof. The power supply 816 may provide power to the computing device 800 to enable the components of the computing device 800 to operate.

The presentation component(s) 818 may include a display (e.g., a monitor, a touch screen, a television screen, a heads-up-display (HUD), other display types, or a combination thereof), speakers, and/or other presentation components. The presentation component(s) 818 may receive data from other components (e.g., the GPU(s) 808, the CPU(s) 806, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to codes that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

At least one embodiment of the disclosure can be described in view of the following clauses:

1. A method comprising: causing one or more hardware components to generate at least one result value based at least on performing one or more diagnostic tests in accordance with at least one diagnostic test pattern; and using the at least one result value to detect one or more hardware faults associated with the one or more hardware components.

2. The method of clause 1, further comprising: causing one or more corrective operations to be performed in response to the one or more hardware faults being detected.

3. The method of clause 1 or 2, further comprising: causing the one or more hardware components to generate the at least one result value based at least on providing the one or more hardware components with one or more input values associated with the at least one diagnostic test pattern.

4. The method of any one of clauses 1-3, wherein the one or more hardware components comprise at least one tensor processor.

5. The method of any one of clauses 1-4, wherein the one or more hardware components are caused to generate the at least one result value in accordance with a diagnostic frequency.

6. The method of any one of clauses 1-5, further comprising: algorithmically generating a portion of the at least one diagnostic test pattern based at least in part on a portion of the one or more hardware components, the portion of the at least one diagnostic test pattern to cause the portion of the one or more hardware components to execute one or more instructions in parallel.

7. The method of any one of clauses 1-6, further comprising: providing an indication of the one or more hardware faults.

8. The method of any one of clauses 1-7, wherein the at least one diagnostic test pattern is to test one or more of: a floating-point vector operation; an integer point vector operation; a matrix multiplication operation; a bit operation; a memory operation; a data path operation; an asynchronous data operation; a cache stride access operation; misaligned cache access; missed buffer access; an operation following a cache compression; or a transfer between the one or more hardware components and a host device.

9. The method of any one of clauses 1-8, further comprising: selecting the at least one diagnostic test pattern from a plurality of pre-existing diagnostic test patterns.

10. A system for use with one or more hardware components and at least one network, the system comprising: one or more processing units; and a network interface to connect the one or more processing units to the one or more hardware components over the at least one network, the one or more processing units to: communicate diagnostic information to the one or more hardware components, via the network interface, to cause the one or more hardware components to generate at least one result value based at least on performing one or more diagnostic tests in accordance with at least one diagnostic test pattern, receive, via the network interface, result information based at least in part on the at least one result value from the one or more hardware components, and use the result information to detect one or more hardware faults associated with the one or more hardware components.

11. The system of clause 10, wherein the one or more processing units are to: cause one or more corrective operations to be performed in response to the one or more hardware faults being detected.

12. The system of clauses 10 or 11, further comprising: one or more control components to perform at least a portion of the one or more corrective operations.

13. The system of any one of clauses 10-12, wherein the diagnostic information comprises one or more input values associated with the at least one diagnostic test pattern.

14. The system of any one of clauses 10-13, further comprising: at least one processor comprising or connected to the one or more hardware components, the network interface to connect the one or more processing units to the one or more hardware components by connecting the one or more processing units to the at least one processor over the at least one network, the one or more hardware components to comprise at least one tensor processor.

15. The system of any one of clauses 10-14, wherein the one or more processing units are to: cause the one or more hardware components to generate the at least one result value in accordance with a diagnostic frequency.

16. The system of any one of clauses 10-15, wherein the one or more processing units are to: generate one or more generated patterns of the at least one diagnostic test pattern based at least in part on the one or more hardware components, at least a portion of the one or more generated patterns to cause at least a portion of the one or more hardware components to execute one or more instructions in parallel.

17. The system of any one of clauses 10-16, wherein the one or more processing units are to: provide an indication of the one or more hardware faults.

18. The system of any one of clauses 10-17, wherein using the result information to detect the one or more hardware faults comprises comparing the at least one result value to at least one expected value associated with the at least one diagnostic test pattern.

19. A processor comprising: one or more processing units to perform operations comprising: causing one or more hardware components to generate at least one result value by performing one or more diagnostic tests in accordance with at least one diagnostic test pattern; and using the at least one result value to detect one or more hardware faults associated with the one or more hardware components.

20. The processor of clause 19, wherein the processor is comprised in at least one of: a control system for an autonomous or semi-autonomous machine; a perception system for an autonomous or semi-autonomous machine; a first system for performing simulation operations; a second system for performing deep learning operations; a third system implemented using an edge device; a fourth system implemented using a robot; a fifth system incorporating one or more virtual machines (VMs); a sixth system implemented at least partially in a data center; a seventh system for performing digital twin operations; an eighth system for performing light transport simulation; a nineth system for performing collaborative content creation for 3D assets; a tenth system for performing conversational Artificial Intelligence operations; an eleventh system for generating synthetic data; a twelfth system for implementing a web-hosted service for detecting program workload inefficiencies; an application as an application programming interface (“API”); a thirteenth system implemented at least partially using cloud computing resources; or a fourteenth system for presenting one or more of virtual reality content, augmented reality content, or mixed reality content.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A method comprising:
causing one or more hardware components to generate at least one result value based at least on performing one or more diagnostic tests in accordance with at least one diagnostic test pattern; and
using the at least one result value to detect one or more hardware faults associated with the one or more hardware components.

2. The method of claim 1, further comprising:
causing one or more corrective operations to be performed in response to the one or more hardware faults being detected.

3. The method of claim 1, further comprising:
causing the one or more hardware components to generate the at least one result value based at least on providing the one or more hardware components with one or more input values associated with the at least one diagnostic test pattern.

4. The method of claim 1, wherein the one or more hardware components comprise at least one tensor processor.

5. The method of claim 1, wherein the one or more hardware components are caused to generate the at least one result value in accordance with a diagnostic frequency.

6. The method of claim 1, further comprising:
algorithmically generating a portion of the at least one diagnostic test pattern based at least in part on a portion of the one or more hardware components, the portion of the at least one diagnostic test pattern to cause the portion of the one or more hardware components to execute one or more instructions in parallel.

7. The method of claim 1, further comprising:
providing an indication of the one or more hardware faults.

8. The method of claim 1, wherein the at least one diagnostic test pattern is to test one or more of:
a floating-point vector operation;
an integer point vector operation;
a matrix multiplication operation;
a bit operation;
a memory operation;
a data path operation;
an asynchronous data operation;
a cache stride access operation;
misaligned cache access;
missed buffer access;
an operation following a cache compression; or
a transfer between the one or more hardware components and a host device.

9. The method of claim 1, further comprising:
selecting the at least one diagnostic test pattern from a plurality of pre-existing diagnostic test patterns.

10. A system for use with one or more hardware components and at least one network, the system comprising:
one or more processing units; and
a network interface to connect the one or more processing units to the one or more hardware components over the at least one network, the one or more processing units to:
communicate diagnostic information to the one or more hardware components, via the network interface, to cause the one or more hardware components to generate at least one result value based at least on performing one or more diagnostic tests in accordance with at least one diagnostic test pattern,
receive, via the network interface, result information based at least in part on the at least one result value from the one or more hardware components, and
use the result information to detect one or more hardware faults associated with the one or more hardware components.

11. The system of claim 10, wherein the one or more processing units are to:
cause one or more corrective operations to be performed in response to the one or more hardware faults being detected.

12. The system of claim 11, further comprising:
one or more control components to perform at least a portion of the one or more corrective operations.

13. The system of claim 10, wherein the diagnostic information comprises one or more input values associated with the at least one diagnostic test pattern.

14. The system of claim 10, further comprising:
at least one processor comprising or connected to the one or more hardware components, the network interface to connect the one or more processing units to the one or more hardware components by connecting the one or more processing units to the at least one processor over the at least one network, the one or more hardware components to comprise at least one tensor processor.

15. The system of claim 10, wherein the one or more processing units are to:
cause the one or more hardware components to generate the at least one result value in accordance with a diagnostic frequency.

16. The system of claim 10, wherein the one or more processing units are to:
generate one or more generated patterns of the at least one diagnostic test pattern based at least in part on the one or more hardware components, at least a portion of the one or more generated patterns to cause at least a portion of the one or more hardware components to execute one or more instructions in parallel.

17. The system of claim 10, wherein the one or more processing units are to:
provide an indication of the one or more hardware faults.

18. The system of claim 10, wherein using the result information to detect the one or more hardware faults comprises comparing the at least one result value to at least one expected value associated with the at least one diagnostic test pattern.

19. A processor comprising:
one or more processing units to perform operations comprising:
causing one or more hardware components to generate at least one result value by performing one or more diagnostic tests in accordance with at least one diagnostic test pattern; and
using the at least one result value to detect one or more hardware faults associated with the one or more hardware components.

20. The processor of claim 19, wherein the processor is comprised in at least one of:
a control system for an autonomous or semi-autonomous machine;
a perception system for an autonomous or semi-autonomous machine;
a first system for performing simulation operations;
a second system for performing deep learning operations;
a third system implemented using an edge device;
a fourth system implemented using a robot;
a fifth system incorporating one or more virtual machines (VMs);
a sixth system implemented at least partially in a data center;
a seventh system for performing digital twin operations;
an eighth system for performing light transport simulation;
a nineth system for performing collaborative content creation for 3D assets;
a tenth system for performing conversational Artificial Intelligence operations;
an eleventh system for generating synthetic data;
a twelfth system for implementing a web-hosted service for detecting program workload inefficiencies;
an application as an application programming interface (“API”);
a thirteenth system implemented at least partially using cloud computing resources; or
a fourteenth system for presenting one or more of virtual reality content, augmented reality content, or mixed reality content.
